(19) United States
(12) Patent Application Publication
(10) Pub. No.: US 2008/0076232 A1
(43) Pub. Date: Mar. 27, 2008

(54) METHOD OF REMOVING IMPURITIES ON A GRINDING SURFACE OF A SEMICONDUCTOR WAFER, EQUIPMENT OF REMOVING IMPURITIES ON A GRINDING SURFACE OF A SEMICONDUCTOR WAFER, PROCESS OF MANUFACTURE OF SEMICONDUCTOR WAFER, PROCESS OF MANUFACTURE OF SEMICONDUCTOR CHIP AND SEMICONDUCTOR DEVICE

(76) Inventor: Kazuyuki HOZAWA, Hino (JP)

Correspondence Address: MILES & STOCKBRIDGE PC, 1751 PINNACLE DRIVE, SUITE 500, MCLEAN, VA, 22102-3833, US

(21) Appl. No.: 11/779,852

(22) Filed: Jul. 18, 2007

(30) Foreign Application Priority Data
Sep. 27, 2006 (JP) JP2006-262057

(51) Int. Cl. H01L 21/00

(52) U.S. Cl. 438/460; 257/E21.002

(57) ABSTRACT

A method of removing impurities on a grinding surface of a thinned semiconductor wafer for producing a highly reliable semiconductor device is provided even when the thickness of a semiconductor chip is thinned. After grinding the back surface of the semiconductor wafer, the impurities on the grinding surface are removed by sandblast processing. The sand particles used in the sandblast processing do not contain copper or nickel, and a concentration of copper or nickel contained in the particles is desirably 10¹⁴ atoms·cm⁻³ or less. After the sandblast processing, compress air is jetted onto the grinding surface of the thinned semiconductor wafer, thereby removing foreign substances, surplus particles or the like on the grinding surface. Then, semiconductor chips are obtained by dicing the thinned semiconductor wafer.

### CROSS-REFERENCE TO RELATED APPLICATION

The present application claims priority from Japanese Patent Application No. JP 2006-262057 filed on Sep. 27, 2006, the content of which is hereby incorporated by reference into this application.

### TECHNICAL FIELD OF THE INVENTION

The present invention relates to a process of manufacture of a semiconductor chip from which impurities on a grinding surface are removed by using sandblast after a semiconductor wafer is thinned by grinding or the like in order to obtain a thin semiconductor wafer with high reliability.

### BACKGROUND OF THE INVENTION

Because electronic devices have downsized and reduced the weight recently, the shape of a semiconductor device is required to be smaller and thinner. Due to such a change in semiconductor device shape, the thinner semiconductor chip is required when it is mounted on the semiconductor device.

Since semiconductor chips are generally obtained from a semiconductor wafer, the semiconductor wafer itself has to be thinned in order to thin the semiconductor chips. However, when semiconductor chips are manufactured by using an already thinner semiconductor wafer from the beginning, there is a strong possibility that the semiconductor itself is damaged. In order to reduce such damage to a semiconductor wafer during semiconductor chip manufacturing, generally, the semiconductor wafer is thinned after forming basic structures of semiconductor chips on the semiconductor wafer surface.

In practice, since many basic structures of semiconductor chips are formed on the top surface of a semiconductor wafer, the back surface of the semiconductor wafer on which the basic structures of the semiconductor chips are not formed has to be uniformly ground so as to thin the wafer.

A general step of grinding a semiconductor wafer is performed separately by a rough grinding step and a fine grinding step. In the rough grinding, the wafer is ground to thickness that is thicker by 20 to 40 μm than the target grinding thickness by using a whetstone having a particle size in a range of #300 to #500. In the fine grinding, the wafer is ground to the target grinding thickness by using a whetstone having a particle size in a range of #2000 to #8000. However, when thickness of the semiconductor wafer is 100 μm or less after grinding by this method, the bending strength of the semiconductor wafer is largely reduced due to the damaged layer (distorted crystal layer) introduced into the grinding surface.

When the thinned semiconductor chips are to be embedded on semiconductor devices in the state in which the bending strength is reduced due to the above-described grinding, the semiconductor chips are damaged during the embedding step. Therefore, when the thickness of the semiconductor wafer is to be thinned to less than 100 μm, generally, the damage layer of the grinding surface introduced by the above-described grinding is removed by dry polishing, CMG (Chemical Mechanical Grinding), wet etching, or the like in order to suppress reduction of the bending strength of the semiconductor wafer.

### SUMMARY OF THE INVENTION

However, there has been a problem that the thinned semiconductor device having a semiconductor chip from which the above-described damage layer is removed tends to readily malfunction.

Therefore, the present inventor has carried out extensive studies for reducing the above described malfunction. As a result, the present inventor has found out that the main reason of the malfunction is that particular impurities, which are adhering to the grinding surface or present in the grinding layer, diffuse into an operation region of the semiconductor chips during the process of embedding the semiconductor chips on the semiconductor devices and the impurities cause the malfunction. The present inventor also has found out that the malfunction of the semiconductor devices are reduced if the semiconductor chips are embedded on the semiconductor devices after removing the impurities of the grinding surface.

In the case that wet etching is utilized to remove the impurities on and in the grinding surface, a liquid mixture containing hydrofluoric acid and nitric acid or an alkaline aqueous solution or the like is generally used.

However, a general grinding apparatus for semiconductor wafer does not have a structure that can resist acidity of hydrofluoric acid, nitric acid and the like, and the alkaline aqueous solution. Even when the structure thereof can resist them, there is a problem that expensive waste fluid equipment for treating hydrofluoric acid and nitric acid or the alkaline aqueous solution is newly required. Also, when CMG is employed, running cost is increased and, in addition, waste fluid equipment is newly required like the wet etching.

Meanwhile, in the case in which the thinned semiconductor wafer is moved to another apparatus so as to remove the impurities on the grinding surface, the thinned semiconductor wafer having a thickness of 100 μm or less cannot sustain the own weight thereof. Therefore, handling or transporting thereof is very difficult, dedicated handling equipment or transporting equipment is required, and moreover, there is a problem that the possibility that the semiconductor wafer is damaged during handling or transporting is increased. The larger the diameter of a semiconductor wafer is, the more conspicuous the tendency becomes.

As a result of extensive studies for solving the above described problems, the present inventor has found out that the malfunction of the semiconductor chips does not readily occur when the impurities adhering to the grinding surface of the semiconductor wafer and the impurities remaining in the grinding surface are removed by using sandblast in thinning the semiconductor wafer. Consequently, the present invention has been made.

Conventionally, the purpose of processing a semiconductor wafer by using sandblast has been intentionally to form a crystal damaged layer on the bottom surface of the semiconductor wafer, which the semiconductor wafer has enough thickness to sustain the own weight thereof, with sand process, and has been to getter the metal contamination existing in the semiconductor wafer to the crystal damaged layer by applying heat treatment to the semiconductor wafer (for example, Japanese Patent Application Laid-Open publication No. 5-29323(Patent Document 1:), Japanese Patent Application Laid-Open publication No. 5-82525(Patent Document 2:), Japanese Patent Application Laid-Open publication No. 11-54519(Patent Document 3:), or Japanese patent Application Laid-Open publication No. 2004-200710 (Patent Document 4:)). These techniques intentionally cause the damage to the crystal on the bottom of the semiconductor wafer. Therefore when the techniques are applied to the very thin semiconductor wafer which is not able to support the own weight, reduction in the bending strength of the semiconductor wafer is caused, and breakage of the semiconductor wafer may occur by merely performing the sandblast.

In general sandblast processing for forming a gettering layer on a semiconductor wafer, sand having a sand particle size of more than 10 μm is used, and wet blasting processing is generally and frequently utilized in terms of dust suppressing, reuse of sand particles or the like.

For example, as shown in Japanese Patent Application Laid-Open publication No. 2000-124170 (Patent Document 5), there is a known example in which the sand particles are small so that they have a particle size in a range of 1 to 8 μm and chelate is added. However, in the case of wet sandblast processing, since fine particles aggregate into larger particles in liquid, the semiconductor wafer is damaged as a result, and the grinding surface of the thinned semiconductor wafer cannot be uniformly removed in the level of several tens of nm.

Therefore, the present invention has been made in view of such problems, and an object of the present invention is to provide a sandblast processing process capable of removing the grinding surface in the level of several nm to several hundreds of nm without damaging even to the grinding surface of the semiconductor wafer, which is thinned so that the wafer cannot support the own weight thereof.

Also, another object of the present invention is to provide techniques capable of producing a highly reliable semiconductor device even when thickness of the semiconductor wafer is thinned to 100 μm or less.

The above-mentioned and other objects and novel characteristics of the present invention will be apparent from the description of the present specification and the accompanying drawings.

The summary of typical ones of the inventions disclosed in the present application will be briefly described as follows.

[1]. In the present invention, when a semiconductor wafer is to be thinned by grinding, impurities adhering to a grinding surface are removed by sandblast.

[2]. Also in the present invention, the impurities described in [1] are copper or nickel, and these are removed by a method of removing impurities using sand particles composed of a material not containing copper or nickel.

[3]. Also in the present invention, a removal rate of an impurity layer removed by removal of impurity on a grinding surface of a semiconductor wafer, which is described in [1], is in a range of 0.2 to 20 nm/min, and thickness of the removed grinding layer is three times or more of an impurity depth in the grinding surface.

[4]. Also In the present invention, according to [1], removal of impurity on a grinding surface of a semiconductor wafer and removal of sand particles adhering to or remaining on a grinding surface with compress air are repeated a plurality of times.

[5]. Also in the present invention, equipment for removing impurities on a grinding surface of a semiconductor wafer has a means for moving or rotating at least one of a jet nozzle and the semiconductor wafer, which are used in the method for removal impurities according to any one of [1] to [4].

[6]. Also in the present invention, a process of manufacture of a semiconductor wafer having a thickness in a range of 5 to 200 μm, the process includes the step of removing impurities of a grinding surface of a semiconductor wafer by equipment of removing an impurities of a grinding surface of a semiconductor wafer according to [5].

[7] . Also in the present invention, a process of manufacture of a semiconductor chip including a step of dicing a semiconductor wafer obtained by the process of manufacture according to [6].

[8]. Also in the present invention, a semiconductor device has a semiconductor chip obtained by the process of manufacture according to [7].

An effect obtained by typical elements of the present invention disclosed in the present application will be briefly described as follows.

Even when the semiconductor chip is thinned, a highly reliable semiconductor device can be provided.

### BRIEF DESCRIPTIONS OF THE DRAWINGS

FIG. 1 is a relation diagram among a Si removal rate, a relative bending strength, and a diameter of sand particle;

FIG. 2 is a cross-sectional view of equipment of removing impurities on a grinding surface of a thinned semiconductor wafer, which is an embodiment of the present invention;

FIG. 3 is a plan view of the equipment of removing impurities schematically showing a step of removing an impurity layer of the thinned semiconductor wafer grinding surface by using the equipment of removing impurities in the present invention;

FIG. 4 is a relation diagram among a Si removal rate, a the relative bending strength, and a sand jet pressure;

FIG. 5 is a relation diagram between a Si removal rate and a relative bending strength;

FIG. 6 is a relation diagram between a Si removal rate, and a distance between a sand jet nozzle and a wafer;

FIG. 7 is a relation diagram between a Si removal rate and an incident angle of sand particle;

FIG. 8 is a relation diagram between a ratio of removing metal contamination of the grinding surface and a removed thickness of the grinding layer; and

FIG. 9 is a flow chart relating to a process of manufacture of a semiconductor device and exemplarily showing a manufactured SiP by the equipment of removing impurities, which is an embodiment of the present invention.

### DESCRIPTIONS OF THE PREFERRED EMBODIMENTS

In all the drawings for explaining present embodiments, those having the same functions are denoted by the same reference numerals, and repetition of explanations thereof will be omitted as much as possible. Hereinafter, embodiments of the present invention will be described in detail with reference to the drawings.

First of all, sand particles which do not cause malfunction of semiconductor chips of the present invention will be described. The sand particles used in the present invention are sand particles not containing copper (Cu) or nickel (Ni), and concentration of copper and nickel contained in the constituent material of the sand particles is desirably not more than 10¹⁴ atoms·cm⁻³. As the above-mentioned particles, for example, fine particles of silicon (Si), silicon oxide, silicon nitride, alumina, silicon carbide, tungsten (W), molybdenum (Mo) and the like are mentioned. The particles may be composed of one or more kinds of them.

The above-described silicon, silicon oxide, or silicon nitride may be a natural product or a synthetic product and preferably contain 10¹⁴ atoms·cm⁻³ or more of boron (B) or phosphorous (P). No particular limitation is imposed on the method to obtain the synthetic product, and the synthetic product obtained at a high temperature and high pressure or by a known method such as the CVD method can be used.

The particles of alumina, silicon carbide, W, Mo and the like obtained by any methods can be used. Also these particles can be obtained as commercial products.

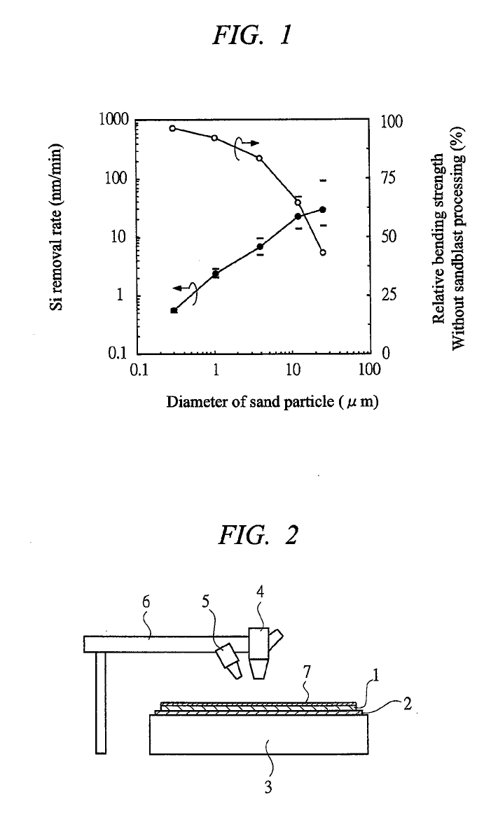

FIG. 1 shows the relation among a Si removal rate, a relative bending strength, and a diameter of sand particle when the equipment of the present invention is used. FIG. 1 shows that, as the diameter of sand particle is larger, the Si removal rate gets increased, and on the contrary, the relative bending strength without blast processing gets reduced. On account of the relation between the Si removal rate and the relative bending strength, it can be found out that the particle diameter of sand used in the present invention is in a range of 0.1 to 30 μm, and desirably in a range of 0.5 to 8 μm from a practical view point.

No particular limitation is imposed on the shape of the particles. For example, the particles may have regular shapes such as the spherical shape or may have irregular shapes. Also, not all the particles may be required to be the primary particles and they may be the secondary particle, i.e. agglomerates.

These sand particles are sprayed onto a grinding surface of a semiconductor wafer, so that impurities on the grinding surface can be removed. Consequently, semiconductor devices on which thinned semiconductor chips from the semiconductor wafer are mounted exhibit high reliability.

Next, equipment of removing impurities on a grinding surface of a semiconductor in the present invention will be described.

The equipment of removing impurities on a grinding surface of a semiconductor wafer in the present invention will be described in detail with reference to FIG. 2. FIG. 2 illustratively shows a main cross-sectional view of equipment of removing impurities on a grinding surface of a semiconductor wafer. The equipment of removing impurities comprises: a thinned semiconductor wafer 1 by grinding; a chuck table 2 to fix the wafer 1; a rotary table 3 causing both the thinned semiconductor wafer 1 and the chuck table 2 for fixing the wafer 1 to be rotated; a sandblast nozzle 4 capable of spraying the sand particles of the present invention; a compress-air jet nozzle 5; and a swing arm 6 causing both the sandblast nozzle 4 and the compress-air jet nozzle 5 to move on the rotary table 3.

First of all, the equipment of removing impurities on a grinding surface of a semiconductor wafer in the present invention has to be able to spray the sand particles of the present invention.

Then, as specific examples of the sand particles, for example, silicon, Silicon oxide, alumina and the like are mentioned.

The concentration of copper or nickel contained in the material of the sand particles has to be 10¹⁴ atoms·cm⁻³ or less. However, no particular limitation is imposed on the particle shape thereof, and the particles may have regular shapes such as the spherical shape or irregular shapes.

The equipment of removing impurities on a grinding surface of a semiconductor wafer of the present invention is required to have a means of rotating or moving at least one of the rotary table 3 and the swing arm 6. When the swing arm 6 is to be simultaneously moved while the rotary table 3 is moved, no particular limitation is imposed on the rotation direction of the rotary table 3 and the moving direction of the swing arm 6.

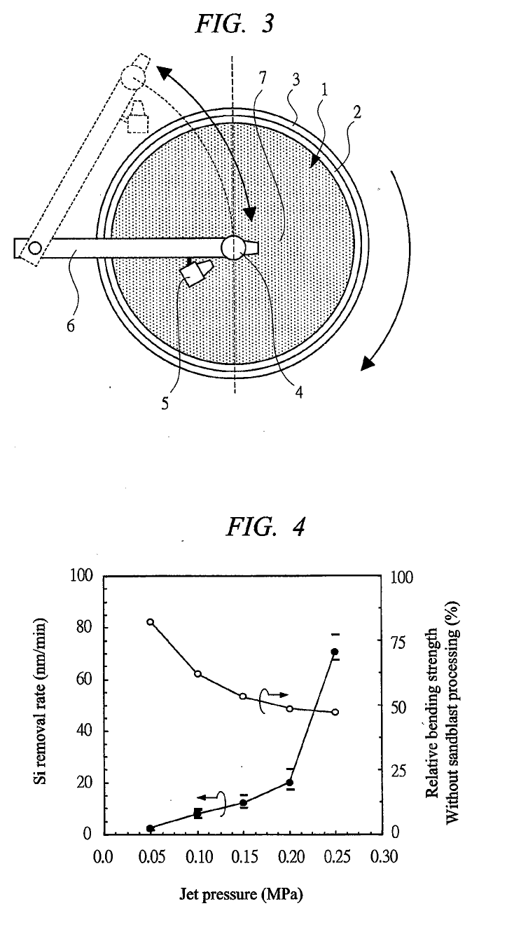

FIG. 3 is a schematic drawing illustratively showing a step of removing impurities on a grinding surface of a semiconductor wafer by using the equipment of removing impurities on a grinding surface a the semiconductor wafer, which can spray the sand particles of the present invention.

A process of manufacture of semiconductor including a step of removing an impurities layer 7 of the grinding surface of the thinned semiconductor wafer 1 by the equipment of removing impurities on a grinding surface of a semiconductor wafer will be described.

The diameter of the rotary table 3 of the equipment of removing impurities illustrated in FIG. 3 is generally in a range of 100 to 500 mm and, preferably, in a range of 200 to 450 mm.

When the impurity layer 7 on the grinding surface of the thinned semiconductor wafer 1 is removed by using the equipment of removing impurities, a rotation speed of the rotary table 3 is normally in a range of 50 to 8000 rpm (revolutions/minute), preferably in a range of 100 to 3000 rpm. The rotation direction, the acceleration/deceleration in rotation speed and the rotation speed of the rotary table 3 can be varied at any time.

A moving speed of the swing arm 6 is normally in a range of 10 to 5000 mm/min and, preferably, in a range of 100 to 2000 mm/min, and the moving speed thereof from the center to the circumference of the rotary table 3 or from the circumference to the center of the rotary table 3 can be varied at any time.

When the number of rotations of the rotary table 3 is constant, the moving speed of the swing arm 6 is gradually reduced while the swing arm 6 moves from the center of the rotary table 3 toward the circumference. Inversely, the moving speed of the swing arm 6 is gradually increased while it moves from the circumference of the rotary table 3 to the center.

On the other hand, when the moving speed of the swing arm is constant, the number of rotations of the rotary table 3 is gradually increased while the swing arm 6 moves from the center of the rotary table 3 toward the circumference. Inversely, the number of rotations of the rotary table 3 is gradually reduced while the swing arm 6 moves from the circumference of the rotary table 3 toward the center.

Also, both the number of rotations of the rotary table 3 and the moving speed of the swing arm 6 can simultaneously be changed at any time.

The number of rotations of the rotary table 3 and the moving speed of the swing arm 6 are appropriately changed, so that the amount of the sand particles sprayed onto a unit area can be constant everywhere on surface of the rotary table 3.

FIG. 4 shows the relation among a Si removal rate, a relative bending strength, and a sand jet pressure. FIG. 4 shows that, as the sand jet pressure increases, the Si removal rate gets increased, and on the contrary, the relative bending strength without sand blast processing gets reduced. When the jet pressure is low, the impurities removal rate is low, and the relative bending strength is not reduced because defects on the impurities removal surface are not readily formed. On the other hand, when the jet pressure is high, the impurities removal rate is high, but the dispersion of the impurities removal rate is large, and also the relative bending strength is largely reduced because defects are readily formed on the surface after removing impurities. According to the above-described relation between the Si removal rate and the relative bending strength, it can be found out that the sand jet pressure used in the present invention is in a range of 0.01 to 0.3 MPa and, desirably, in a range of 0.03 to 0.2 MPa from a practical viewpoint.

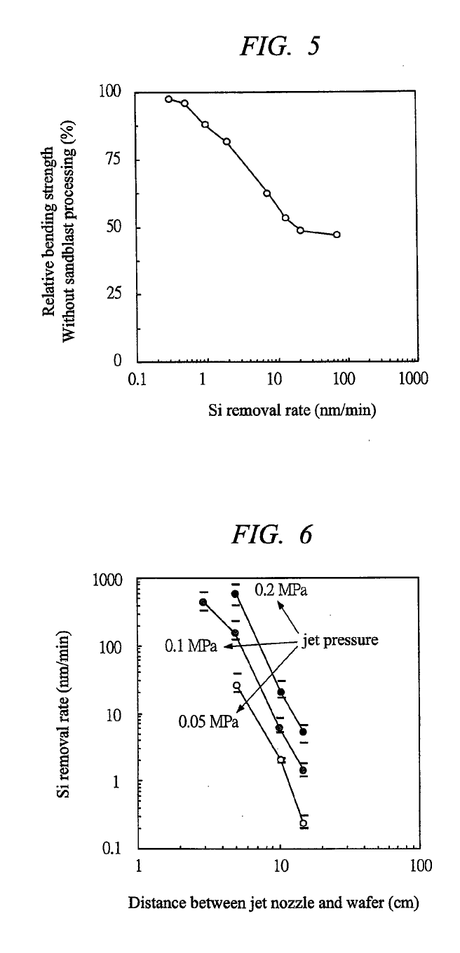

FIG. 5 shows the relation between a Si removal rate and a relative bending strength. FIG. 5 shows that the relative bending strength is reduced when the Si removal rate is increased. From the viewpoint of prevention of damage to semiconductor wafers, the relative bending strength is required to be at least 50%, and at the same time the Si removal rate is about 20 nm/min. When impurities of a grinding surface of a thinned semiconductor wafer are present merely on the wafer surface (the case in which they are not present in the grinding surface), the grinding surface has to be removed by at least 1 nm in order to remove the impurities on the surface. Furthermore, from the viewpoint of throughput, since processing time for one semiconductor wafer has to be five minutes or less, the Si removal rate is required to be 0.2 nm/min or more. As a result, the Si removal rate used in the present invention is in a range of 0.2 to 20 nm/min, and more desirably, the Si removal rate, which causes the relative bending strength to be 75% or more, is in a range of 1.0 to 3.0 nm.

FIG. 6 shows the relation between a Si removal rate and a distance between a sand jet opening (nozzle opening) and a semiconductor wafer. FIG. 6 shows that the Si removal rate gets increased as the distance between the nozzle opening and the semiconductor wafer becomes shorter, and the Si removal rate varies depending on the jet pressure. The Si removal rate is low when the distance between the sand jet opening and the semiconductor wafer is long, and inversely the Si removal rate is high when the distance between the sand jet opening and the wafer is short. However, although it is not shown in the figure, the relative bending strength is reduced because defects on the surface after removing impurities are readily formed when the removal rate is high. As a result, it has been found out that the distance between the sand jet opening and the semiconductor wafer used in the present invention is in a range of 1 to 30 cm, and desirably it is in a range of 3 to 15 cm from a practical viewpoint.

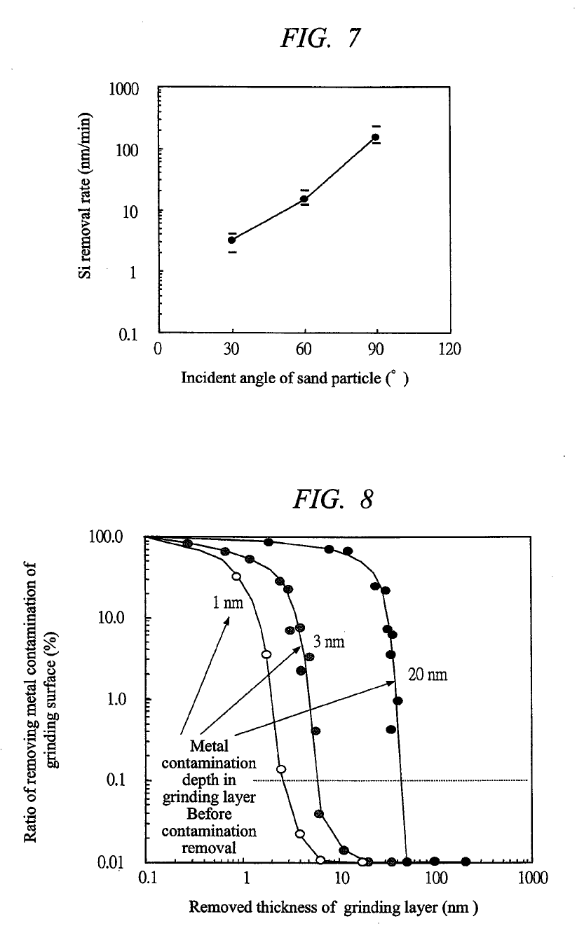

FIG. 7 shows the relation between a Si removal rate and an incident angle of sand particles. FIG. 7 shows that the Si removal rate is increased as the incident angle of sand particles gets closer to 90°, and that the Si removal rate is largely reduced as the angle gets closer to 0°. When the incident angle of the sand particles is smaller than 90°, the sand particles readily reflect on the grinding surface, and the amount of sand particles injected into the grinding surface is reduced, so that the Si removal rate is reduced. As a result, it has been found out that the incident angle of sand particles in the present invention is in a range of 30° to 90° and desirably, in a range of 60° to 90° from the practical viewpoint.

As it can be understood from the results of FIG. 1, FIG. 4, FIG. 6, and FIG. 7, the Si removal rate can be arbitrarily varied by changing the diameter of sand particles, the sand jet pressure, the distance between the nozzle opening and the semiconductor wafer, and the incident angle of the sand particles.

FIG. 8 shows the relation between a ratio of removing metal contamination of the grinding surface and a removed thickness of the grinding layer. Three kinds of samples having the different metal contamination depths in the grinding layers, which are obtained with different methods for grinding semiconductor wafers, are tested. The depth of the metal contamination in the grinding layer is repeatedly measured with acid cleaning of removing the grinding layer and by total reflection X-ray fluorescence analysis (TXRF). It can be understood from FIG. 8 that the ratio of removing metal contamination on the grinding surface is reduced as the thickness of the removed grinding layer is increased and furthermore that the deeper the metal contamination depth in the grinding layer before contamination removal is, the harder to reduce the ratio of removing metal contamination of the grinding surface is.

FIG. 8 also shows that the ratio of removing metal contamination is 0.1% or less when the grinding layer is removed by about three times or more the metal contamination depth in the grinding layer. The depth of a general impurities layer formed by back grinding (BG) and dry polishing (DP) is not more than 100 nm at most. Therefore, according to the relation between the ratio of removing metal contamination of the grinding surface and the removed thickness of the grinding layer, the removed thickness of the grinding layer in the present invention is 300 nm or less.

After the impurity removal, in order to remove foreign substances, surplus sand particles or the like remaining on the grinding surface of the thinned semiconductor wafer 1, clean dry air or nitrogen or the like is jetted from the compress air jet nozzle 5. The flow rate of the dry air or nitrogen or the like is normally in a range of 10 to 1000 1/min, and preferably in a range of 100 to 500 1/min. Meanwhile, the dry air or nitrogen jetted from the compress air jet nozzle 5 is jetted in an oblique direction to the thinned semiconductor wafer 1, so that the remaining foreign substances, surplus sand particles or the like remaining on the grinding surface can be efficiently removed.

Further, the removal of impurities by sandblast and removal of the foreign substances and surplus sand particles by the compress air jet nozzle 5 are repeated a plurality of times, so that the damage to the grinding surface of the semiconductor wafer 1 can be suppressed and the metal contamination removal efficiency can be improved.

The thickness of the obtained semiconductor wafer 1 in this manner is in a range of 5 to 200 μm, preferably in a range of 30 to 100 μm, and more ideally, in a range of 50 to 70 μm.

When the thickness of the semiconductor wafer 1 is in the range a 5 to 200 μm, highly reliable semiconductor devices can be produced.

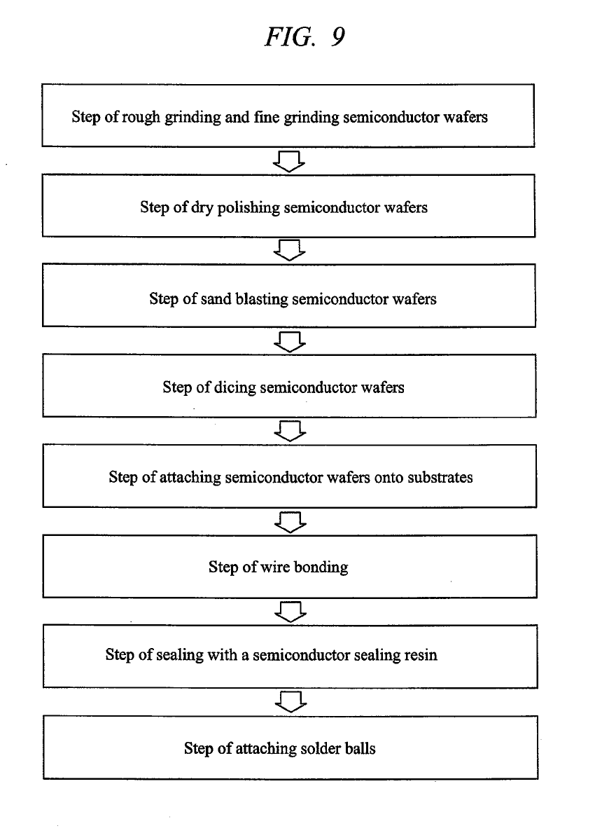

Next, a process of manufacture of a semiconductor chip and a semiconductor device having the semiconductor chip will be described in accordance with the flow chart exemplarily shown in FIG. 9, wherein the case of SiP (System In Package) is taken as one of embodiments.

First of all, in order to thin the semiconductor wafer 1, rough grinding and fine grinding of the back surface of the semiconductor wafer 1 are performed, and further a dry polishing process is performed for removing the damaged layer of the grinding surface. After the dry polishing process of the semiconductor wafer 1, in order to remove an impurity layer adhering to the grinding surface, the impurity layer is removed by sandblast of the present invention.

Subsequently, the semiconductor wafer 1 is cut in dicing step, whereby semiconductor chips are obtained.

The semiconductor chip is attached onto a SiP substrate and wired to the substrate with Au wires or the like by wire bonding. The semiconductor chip mounted on the SiP substrate is sealed by a semiconductor sealing resin, and then is subjected to after-curing at 175° C. for five hours, thereby performing a sealing step.

Next, Solder balls are attached onto a SiP package in a step of reflow, so that the SiP package can be obtained.

As described above, according to the present embodiment, the semiconductor wafer 1 from which the impurities that cause malfunction of the semiconductor chip are removed can be obtained by removing impurities adhering to or remaining on the grinding surface of the semiconductor wafer by using the sand particles of the present invention by the equipment of removing impurities of the present invention.

Under the condition that the semiconductor device is manufactured by using the semiconductor chip obtained from the semiconductor wafer 1, the impurities on the grinding surface that cause malfunction of the semiconductor chip are removed, and therefore, there is no impurity that reach the basic structure part of the semiconductor chip formed on the surface of the semiconductor wafer 1.

Therefore, semiconductor devices obtained by using the semiconductor chip exhibit high reliability.

The embodiment of the present invention will be described in further detail with reference to examples below. However, the present invention is not limited to the contents of the examples below.

### FIRST EXAMPLE

First of all, sand particles will be described. Silicon oxide particles (diameter: about 3 to 5 μm) having a copper concentration of 10¹⁴ atoms·cm⁻³ or less and a particle size of #3000 were used as the sand for sandblast.

### SECOND EXAMPLE

Next, a process of manufacture of a semiconductor wafer and a semiconductor device chip will be described by using the equipment of removing impurities on a grinding surface of a semiconductor wafer, which is provided with the sand particles obtained from the first example.

A semiconductor wafer having semiconductor elements for FLASH memories formed on the surface thereof was roughly ground to 100 μm by using a diamond whetstone having a particle size of #300 and then was finely ground to 72 μm by using a diamond whetstone having a particle size of #2000. Then, the damage layer of the grinding surface was completely removed after grinding it by 2 μm by dry polishing. The thickness of the obtained semiconductor wafer was 70 μm.

Then, impurities adhering to the grinding surface of the thinned semiconductor wafer were removed by using the equipment of removing impurities on a grinding surface of a semiconductor wafer. Meanwhile thickness of the removed grinding layer was about 50 nm on average.

Semiconductor chips were obtained by dicing the semiconductor wafer.

### THIRD EXAMPLE

Next, a semiconductor device having the semiconductor chip obtained in the second example will be described. After attaching the semiconductor chip obtained in the second example to a SiP substrate, the semiconductor chip and the SiP substrate were mutually connected by Au wires by wire bonding. Subsequently, they were subjected to a transfer molding with a semiconductor sealing resin and were subjected to after-curing under the condition at 175° C. and for five hours.

After the after-curing, a step of attaching solder balls was performed by performing reflow at 220° C. and a semiconductor device as a FLASH memory having a SiP package mode was obtained.

The semiconductor device obtained in this manner will be referred to as a semiconductor device A.

A certain number of the obtained semiconductor devices A were used, repeatedly erased and rewritten at a room temperature so that a fluctuation in the threshold voltage of the FLASH memories was measured before and after erasing and rewriting. When the fluctuation in the threshold voltage fluctuated over the allowable value of as a product, it was determined as a defective product, and a test of checking the yield was carried out under this condition. When the yield in this case is considered as 100%, and relative results of first and second comparative examples described as follows are shown in table 1.

### FIRST COMPARATIVE EXAMPLE

Semiconductor devices were obtained by performing entirely the same operations as those of the second example and third example, except that the impurities on the grinding surface of the thinned semiconductor wafer were not removed in the second example. The semiconductor devices obtained in this process will be referred to as semiconductor devices B.

### SECOND COMPARATIVE EXAMPLE

Semiconductor devices were obtained by performing entirely the same operations as the second embodiment and the third embodiment, except that a copper concentration of the sand particles was about 10¹⁶ atoms·cm⁻³ when the impurities on the grinding surface of the thinned semiconductor wafer were removed in the second example. The semiconductor devices obtained in this process will be referred to as the semiconductor devices C.

TABLE 1

| | RELATIVE YIELD (%) |
|---|---|
| SEMICONDUCTOR DEVICE A | 100 |
| SEMICONDUCTOR DEVICE B | 52 |
| SEMICONDUCTOR DEVICE C | 4 |

The invention made by the present inventor has been specifically described hereinabove based on the embodiments. However, the present invention is not limited to the above-described embodiments, and it goes without saying that various modifications can be made without departing from the scope of the invention.

For example, although the case of application to a semiconductor device for SiP has been described in the above-described embodiment, no limitation is imposed thereon. For example, the invention can be applied to a semiconductor device for a memory, wherein a semiconductor chip for a memory circuit is mounted on a wiring circuit and a semiconductor chip for the control circuit to control the operation of the memory circuit is stacked on the semiconductor chip for the memory circuit and these semiconductor are sealed with a resin sealing body.

The present invention can be applied to the manufacturing industry of semiconductor devices.

1-15. (canceled)

16. A process of manufacture of a semiconductor chip comprising the steps of:
(a) a step of grinding a back surface of a semiconductor wafer;
(b) a step of removing impurities on a grinding surface of the semiconductor wafer by sandblast; and
(c) a step of obtaining the semiconductor chip by dicing the semiconductor wafer after the step (b).

17. The process of manufacture of a semiconductor chip according to claim 16,
wherein a constituent material of sand particles of the sandblast does not contain copper or nickel.

18. The process of manufacture of a semiconductor chip according to claim 16,
wherein a removal rate of an impurity layer removed by impurity removal of the grinding surface of the semiconductor wafer is in a range of 0.2 to 20 nm/min.

19. The process of manufacture of a semiconductor chip according to claim 16,
wherein thickness of the impurity layer removed by impurity removal of the grinding surface of the semiconductor wafer is three times or more an impurity depth of the grinding surface.

20. The process of manufacture of a semiconductor chip according to claim 16,
wherein the step (b) includes a step of repeating impurity removal of the grinding surface of the semiconductor wafer and removal of sand particles remaining on the grinding surface by compress air a plurality of times.

21. A semiconductor device comprising a semiconductor chip obtained by:
(a) grinding a back surface of a semiconductor wafer;
(b) removing impurities on a grinding surface of the semiconductor wafer by sandblast; and
(c) dicing the semiconductor wafer after the step (b).

22. The semiconductor device according to claim 21,
wherein a constituent material of sand particles of the sandblast does not contain copper or nickel.

23. The semiconductor device according to claim 21,
wherein a removal rate of an impurity layer removed by impurity removal of the grinding surface of the semiconductor wafer is in a range of 0.2 to 20 nm/min.

24. The semiconductor device according to claim 21,
wherein thickness of the impurity layer removed by impurity removal of the grinding surface of the semiconductor wafer is three times or more an impurity depth of the grinding surface.

25. The semiconductor device according to claim 21,
wherein the step (b) includes a step of repeating impurity removal of the grinding surface of the semiconductor wafer and removal of sand particles remaining on the grinding surface by compress air a plurality of times.
